(19) United States
(12) Patent Application Publication
(10) Pub. No.: US 2013/0140517 A1
(43) Pub. Date: Jun. 6, 2013

(54) Thin and Flexible Gallium Nitride and Method of Making the Same

(71) Applicants: Liang Tang, West Lafayette, IN (US); Yuefeng Wang, West Lafayette, IN (US); Michael Manfra, West Lafayette, IN (US); Gary Cheng, West Lafayette, IN (US); Timothy Sands, West Lafayette, IN (US)

(72) Inventors: Liang Tang, West Lafayette, IN (US); Yuefeng Wang, West Lafayette, IN (US); Michael Manfra, West Lafayette, IN (US); Gary Cheng, West Lafayette, IN (US); Timothy Sands, West Lafayette, IN (US)

(73) Assignee: PURDUE RESEARCH FOUNDATION, West Lafayette, IN (US)

(21) Appl. No.: 13/538,590

(22) Filed: Jun. 29, 2012

Related U.S. Application Data
(60) Provisional application No. 61/502,816, filed on Jun. 29, 2011.
(60) Provisional application No. 61/502,820, filed on Jun. 29, 2011.
(60) Provisional application No. 61/502,823, filed on Jun. 29, 2011.
(60) Provisional application No. 61/502,826, filed on Jun. 29, 2011.

(51) Int. Cl. H01L 21/36; H01L 29/20

(52) U.S. Cl. CPC H01L 21/36; H01L 29/2003; Y10S 977/70; B82Y 40/00
USPC 257/9; 438/478

(57) ABSTRACT

A material for use in electronic circuits. The material includes a thin layer of gallium nitride (GaN), the thin layer of GaN produced in a high-volume production setting without mechanical planarization having a thickness of as low as 10 nm and a defect density as low as 10⁵ per cm².

### CROSS-REFERENCE

The present U.S. patent application is related to and claims the priority benefit of U.S. Provisional Patent Application Ser. Nos. 61/502,816, filed Jun. 29, 2011, and 61/502,820, filed Jun. 29, 2011, 61/502,823, filed Jun. 29, 2011, and 61/502,826, filed Jun. 29, 2011, the contents of each of which is hereby incorporated by reference in its entirety into this disclosure.

### TECHNICAL FIELD

This disclosure relates to high quality thin films of gallium nitride (GaN) and flexible films of GaN, and to methods of making the same.

### BACKGROUND

Due to their direct bandgap and large tunable bandgap range, Gallium nitride (GaN) and related nitride compounds (InGaN, InAlN, and AlGaN) are widely used for optoelectronic and microelectronic devices, including light emitting diode (LED) devices, optical detectors, and high speed high power transistors. LED lights, for example, are efficient, reliable, and solid-state. Gallium nitride is used for most LED device manufacturing. Similar to silicon, GaN is now widely used in semiconductor industry. However, nearly all GaN and nitride products are rigid, relatively thick, and costly. Making flexible GaN has been a difficult task and there have been very few successes.

Most recently, news from Yale University reported that Jung Han et al. developed a technique called nanoetching, which is similar to the anodization process in electrolytes, as known to a person having ordinary skill in the art. According to their methods, a GaN film was etched into porous structures with semi-directional pores normal to the film surface under low a voltage condition. Then, by tuning up the voltage for etching, the pores branch out in random directions. Finally, the pores break across the GaN surface, and the top porous structure may be released. However, one challenge is that during the etching process the top porous GaN structure is continuously etched, as well as the bulk GaN, which yields poor quality GaN. There are also limitations on the thickness which can be fabricated due to kinetics in the etching process.

Richard C. Cope described an approach to realize flexible displays (see U.S. Pat. App. 2009/0219225 for Cope). The display panel contains a plurality of pixel chips and lighting units, all on a flexible film. In the Cope approach, multiple units are utilized on a flexible film. With current resolution requirements, hundreds of millions pixels are needed for desired resolution. Manufacturing costs for this type of product are predicted to be extraordinarily high. Wiring and controlling systems could also raise challenges.

In-Jae Song, et al. disclosed etching GaN using HCl and NH₃ gases and forming a porous layer to lift off the GaN substrate. The Song method allows the etching process to be performed within the same growth chamber (see U.S. Pat. App. 2007/0082465 for Song).

Z. S. Luo, et al. disclosed a method utilizing a UV laser to lift off GaN substrate and transfer the GaN substrate from sapphire to silicon. The Luo group fabricated nitride LEDs including Indium Nitride and GaN on sapphire substrate. Then, by a laser lift-off and Palladium-Indium (Pd—In) bonding processes after the transfer, the GaN top structures were transferred onto silicon wafer (see also U.S. Pat. No. 6,071,795 to Cheung et al.).

Yuichi Oshima, et al. developed a technique for preparing freestanding GaN wafers by growing GaN by Hydride Vapor Phase Epitaxy (HVPE) on TiN masks. The voids generated near the mask serve as a separation layer. (See J. Appl. Phys., Vol. 42, 2003). The above techniques require voids or pores for separating, which could extend into the GaN film and cause degradation in crystal quality.

W. S. Wong, et al. developed a method of using UV laser to lift off GaN from a sapphire substrate. The Wong method grew GaN film on sapphire substrate. Then by laser irradiation which decomposed the interface between GaN and sapphire and Pd—In bonding after transfer, the GaN top structures was lifted. The Wong method has been the standard method for fabricating freestanding GaN substrate in industry. However, only one GaN substrate can be lifted from one sapphire wafer and the separating interface is defect rich, and therefore a thick dislocation blocking GaN layer is required on top of the separating interface to reduce defects (see W. S. Wong, T. Sands and N. W. Cheung, Appl. Phys. Lett. 72 (1998) pp. 599-601).

To address the challenges described herein, a novel freestanding thin film of GaN is needed in addition to a novel thin film of GaN that can be configured to be flexible.

### SUMMARY

A material for use in electronic circuits is disclosed. The material includes a thin layer of gallium nitride (GaN). The thin layer of GaN is produced in a high-volume production setting without mechanical planarization having a thickness of as low as 10 nm and a defect density as low as 10⁵ per cm².

A method of making a material for use in electronic circuits produced in a high-volume production setting is disclosed. The method includes forming a thick buffer layer of gallium nitride (GaN) on a substrate. The method further includes forming a support structure on the thick buffer layer of GaN. In addition, the method includes forming a thin epilayer of GaN on top of the support structure. The method also includes disrupting the support structure substantially without causing defects in the thin epilayer of GaN. Additionally, the method includes removing the thin epilayer of GaN from the disrupted support structure. The thin epilayer of GaN having a thickness of as low as 10 nm and a defect density as low as 10⁵ per cm².

### BRIEF DESCRIPTION OF DRAWINGS

The above-mentioned and other features of this disclosure will become more apparent and the disclosure itself will be better understood by reference to the following brief description of drawings.

FIG. 1 is a schematic of a lamellar structure including a substrate, a thick buffer gallium nitride (GaN) layer, and a plurality of a combination of a superlattice support structure, which includes a plurality of alternating atomic monolayers of indium nitride (InN) and GaN, and a thin epilayer of GaN.

FIG. 2 is a schematic of irradiation of laser from the bottom side of a portion of the lamellar structure shown in FIG. 1 in order to decompose an interface layer of the thick buffer GaN layer near the substrate, resulting in a highly defective region.

FIGS. 3A, 3B, 3C, and 3D are schematics of various intermediate process steps to achieve the lamellar structure depicted in FIG. 1.

FIG. 4 is a schematic of the lamellar structure depicted in FIG. 1 with additional detail.

FIG. 5 is a schematic of irradiation of laser from the top side of a portion of the lamella structure shown in FIG. 1 in order to decompose the top most superlattice support structure resulting in decomposition of InN into In and nitrogen and the breakup of GaN monolayers.

FIG. 6 is a schematic of the top most thin epilayer of the GaN and the associated superlattice support structure (not shown) of FIG. 5, where the top most thin epilayer of GaN is separated and the associated superlattice support structure is removed.

FIG. 7 is a flow chart diagram of various process steps depicted in FIGS. 3A through 6.

FIG. 8 is a schematic of a lamellar structure including a substrate, a thick buffer GaN layer, and a plurality of a combination of a support structure, which includes a plurality of GaN nanorods, and a thin epilayer of GaN.

FIGS. 9A, 9B, 9C, 9D, 9E, and 9F are schematics of various intermediate process steps to achieve the lamellar structure depicted in FIG. 8.

FIG. 10 is a schematic of a shearing process of the support structure depicted in FIG. 8.

FIG. 11 is a schematic of the top most epilayer of GaN depicted in FIG. 8 removed from the lamellar structure.

FIG. 12 is a schematic of an intermediate epilayer of GaN depicted in FIG. 8 removed from the lamellar structure.

FIG. 13 is a flow chart diagram of various process steps depicted in FIGS. 9A through 12.

FIG. 14 is a schematic of a lamellar structure including a substrate, a thick buffer GaN layer, and a plurality of a combination of a superlattice support structure, which includes a plurality of alternating layers of InN and GaN, a thin epilayer of GaN, and an epitaxial GaN structure.

FIGS. 15A, 15B, 15C, 15D, 15E, 15F, 15G, 15H, 15I, and 15J are schematics of various intermediate process steps to achieve the lamellar structure depicted in FIG. 14.

FIG. 16 is a schematic of one combination of a thin epilayer of GaN and an epitaxial GaN structure formed by a growth process to have a plurality of pores which is separated from the lamellar structure depicted in FIG. 14.

FIG. 17 is a schematic top view of the epitaxial GaN structure with its plurality of pores depicted in FIG. 16.

FIGS. 18A, 18B, 18C, and 18D are schematics of various intermediate process steps to achieve the lamellar structure depicted in FIG. 14 according to an alternative embodiment.

FIG. 19 is a schematic of one combination of a thin epilayer of GaN and an epitaxial GaN structure formed by an etching process to have a plurality of pores which is separated from the lamellar structure depicted in FIG. 14.

FIG. 20 is a flow chart diagram of various process steps depicted in FIGS. 15A through 15J and FIGS. 18A through 18D.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

A novel freestanding thin film of gallium nitride (GaN) and a novel thin film of GaN that can be configured to be flexible, along with novel processes to achieve said structures have been disclosed herein.

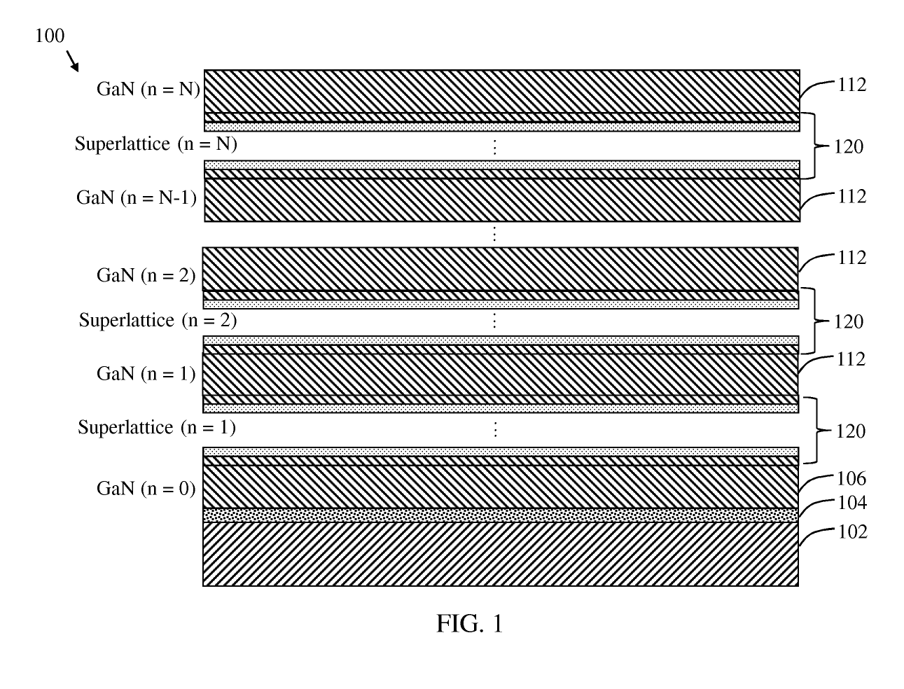

Referring to FIG. 1, a schematic of a lamellar structure 100 is depicted. The lamellar structure 100 includes a substrate 102, a thick buffer GaN layer 106, resulting in a defect rich thin layer 104, and a plurality of a combination of a superlattice support structure 120, which includes a plurality of alternating layers of indium nitride (InN) and GaN, and a thin epilayer of GaN 112, described further below. The substrate 102 can be sapphire as it is known that the combination of sapphire and GaN enables growth of epitaxial crystalline GaN. The thick buffer GaN layer 106 is sufficiently thick to compensate for the lattice mismatch between GaN and the substrate 102. However, the interface region between the substrate 102 and the thick buffer GaN layer 106 results in the defect rich thin layer 104. GaN crystal quality improves as GaN grows thicker.

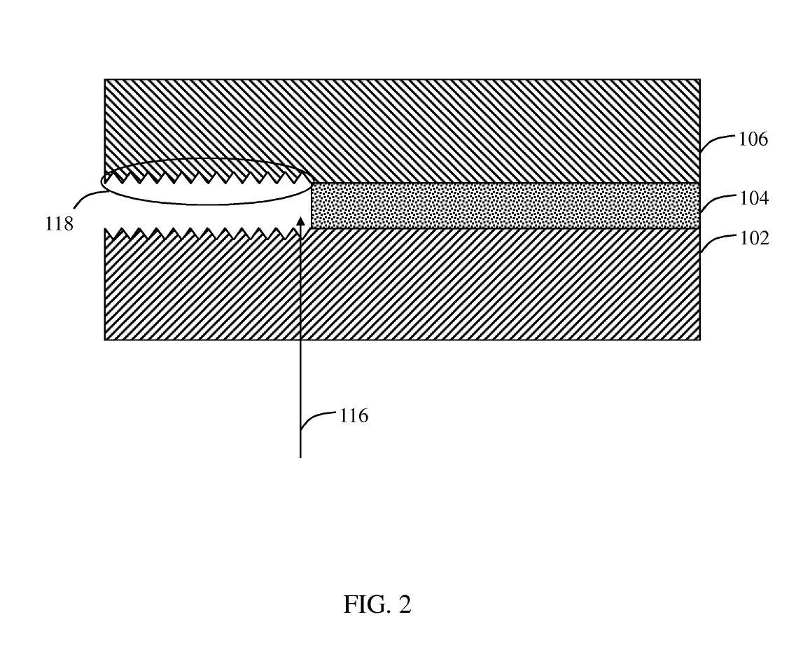

To further illustrate disadvantage with the prior art, reference is made to FIG. 2. Prior art teaches techniques to optically decomposed the defect rich thin layer 104 by laser 116 irradiation directed at the defect rich thin layer 104. The laser 116 is applied from the bottom side. The laser is absorbed by GaN resulting in a high defect region 118. To overcome the high defect yield, process steps to achieve the novel structure of FIG. 1 is now further described.

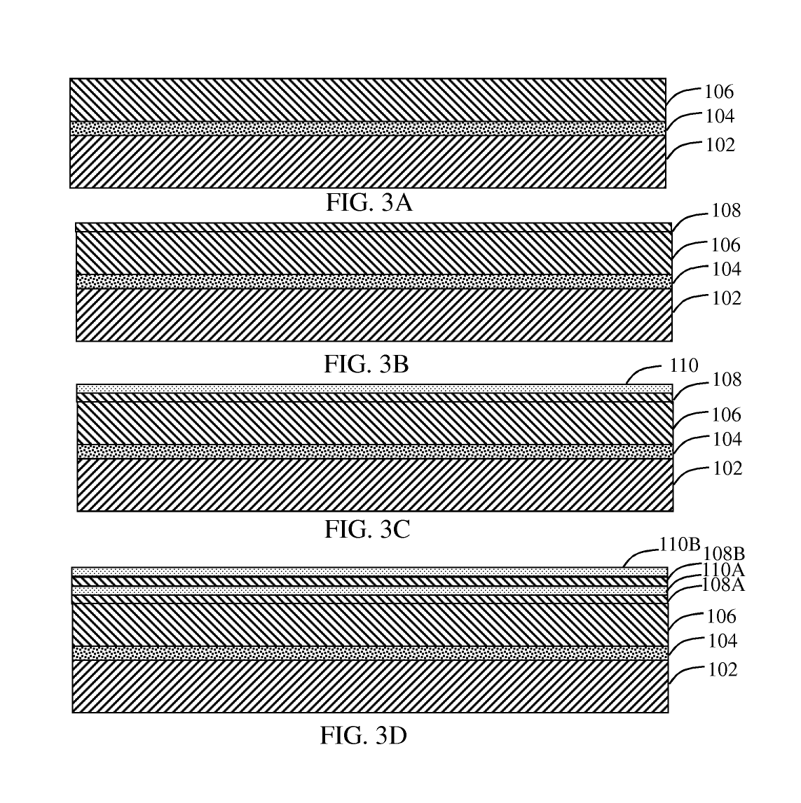

Referring to FIGS. 3A, 3B, 3C, and 3D schematics of various intermediate process steps to achieve the lamellar structure depicted in FIG. 1 are presented.

Referring to FIG. 3A, the thick buffer GaN layer 106 is formed on the substrate 102. The thick buffer GaN layer 106 is formed according to an epitaxial growth process known to a person having ordinary skill in the art.

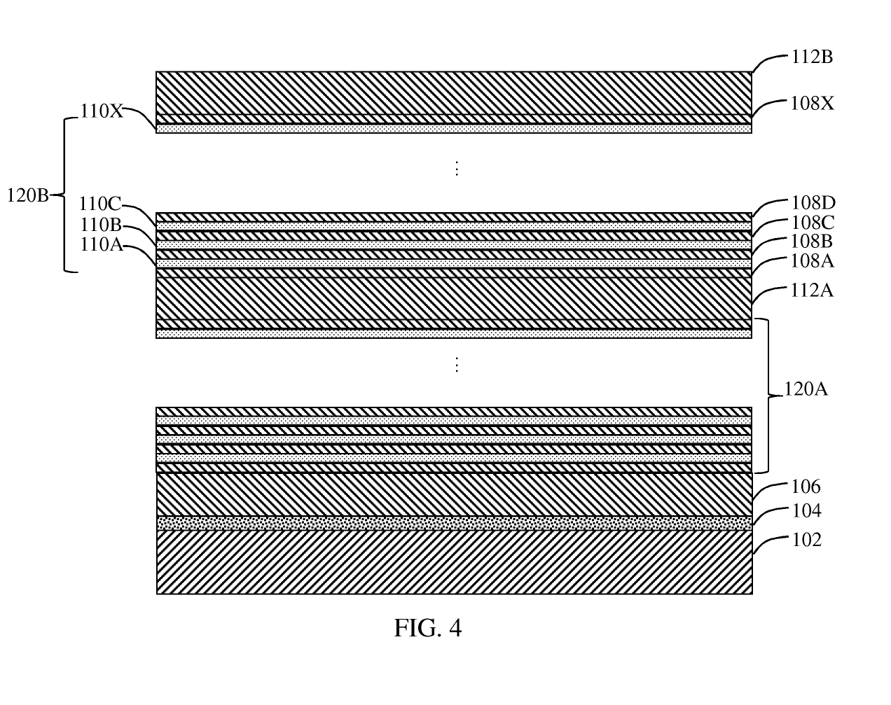

Referring to FIG. 3B, a layer 108 of GaN is deposited on the thick buffer GaN layer 106. Referring to FIG. 3C, a layer 110 of InN is deposited on top of the layer 108 of GaN. Thereafter, alternating thin layers 108 and 110 of GaN and InN, respectively, are deposited to form a superlattice support structure 120. These alternating layers are referenced as 108A, 110A, 108B, 110B, 108C, 110C, 108D, 108X, and 110X, as depicted in FIGS. 3D and 4. These layers are alternately deposited by either Metal Organic Chemical Vapor Deposition (“MOCVD”), also known as Metal Organic Vapor Phase Epitaxy (“MOVPE”) and Organometallic Vapor Phase Epitaxy (“OMVPE”), or Molecular Beam Epitaxy (“MBE”). Because of the large lattice mismatch between InN and GaN, the critical thickness for InN on GaN is small. Therefore to preserve crystal quality, a very thin layer of InN is needed. To ensure separation, as discussed below, over large areas, as well as to compensate for the quantum size effect, multiple alternating layers of InN/GaN are stacked together in the form of superlattice support structure 120. According to an alternative embodiment, within the superlattice support structure 120, in place of InN, high In composition and high InGaN compositions can also be used as laser absorption layer, to effect decomposition, as described further below. Low In composition and low InGaN composition, can be used in place of the In—GaN superlattice support structure 120 (with bandgap >2 eV), which could serve to reduce the lattice mismatch and improve epilayer quality. According to another alternative embodiment, high Indium composition layers may take the place of Indium Nitride. Low Indium composition layers may take place of GaN.

Further referring to FIG. 4, thin epilayers of GaN 112A and 112B are deposited on top of the superlattice support structure 120A and 120B by MOCVD or MBE. Functional devices (with low Indium composition, bandgap >2 eV) such as light emitting diode (LED), transistors, multiple quantum well devices (“MQW”) can be manufactured from thin epilayer of GaN 112 in the same deposition process. In alternative embodiments, a bonding layer such as In or Lead can be placed on top to assist in strengthening the mechanical property of the top GaN layer during the separation process as described below. In accordance to at least one embodiment, the thin epilayer of GaN 112 can have a thickness as low as 10 nm, and each of the alternating thin layers 108 and 110 of GaN and InN, respectively, can be atomic monolayers. In accordance to at least one embodiment 30-60 layers of GaN (108) and InN (110) bilayers can be deposited to generate one superlattice support structure 120. In accordance to another embodiment, only one layer 110 of InN can constitute the superlattice support structure.

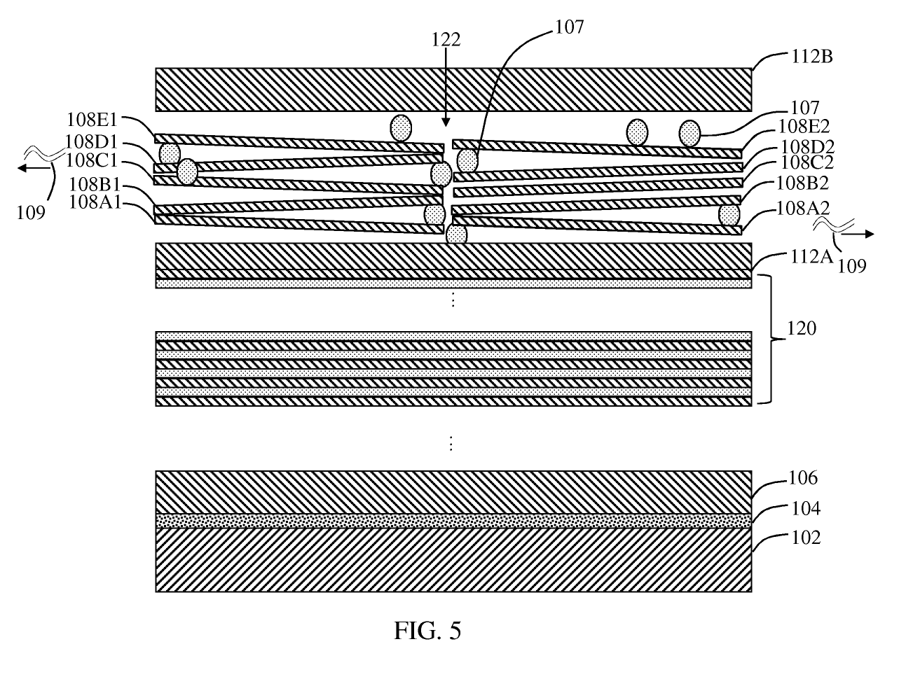

Referring to FIG. 5, a schematic of irradiation of pulsed laser 122 from the top side of a portion of the lamellar structure 100 shown in FIG. 1 is depicted in order to decompose the top most superlattice support structure 120 resulting in decomposition of InN into In 107 and nitrogen 109 and the breakup of GaN layers (into 108A1, 108A2, 108B1, 108B2, 108C1, 108C2, 108D1, 108D2, 108E1, and 108E2). The pulsed laser 122 is shone upon the lamellar structure 100 from the top side. The photon energy is transparent to GaN (i.e., layers 108, 106, and 112) and the substrate 102 but such photon energy is absorbed by the InN layer 110 (and all other indices of 110, i.e., 110A, 110B, etc.) of superlattice support structure 120. The absorption would occur between 0.7 eV and 3.4 eV. The laser pulse 122 includes sufficient power to achieve the desired decomposition (according to at least one embodiment: greater than 50 mJ/cm²), i.e., the laser pulse 122 provides sufficient heating in order to decompose InN layers 110. Duration of pulse 22 is in nanoseconds such that absorbed energy is concentrated within the desired areas causing rapid local heating without significant heat dissipation. According to an alternative embodiment, the laser pulse 122 can be shone from the bottom side (i.e., form the substrate 102 side). This alternative embodiment is directed to cases where various devices (such as light emitting diodes) are integrated (i.e., embedded) at the top thin epilayer 112 of GaN. In such a situation, irradiating the top thin epilayer 112 of GaN can cause damage to the integrated/embedded devices.

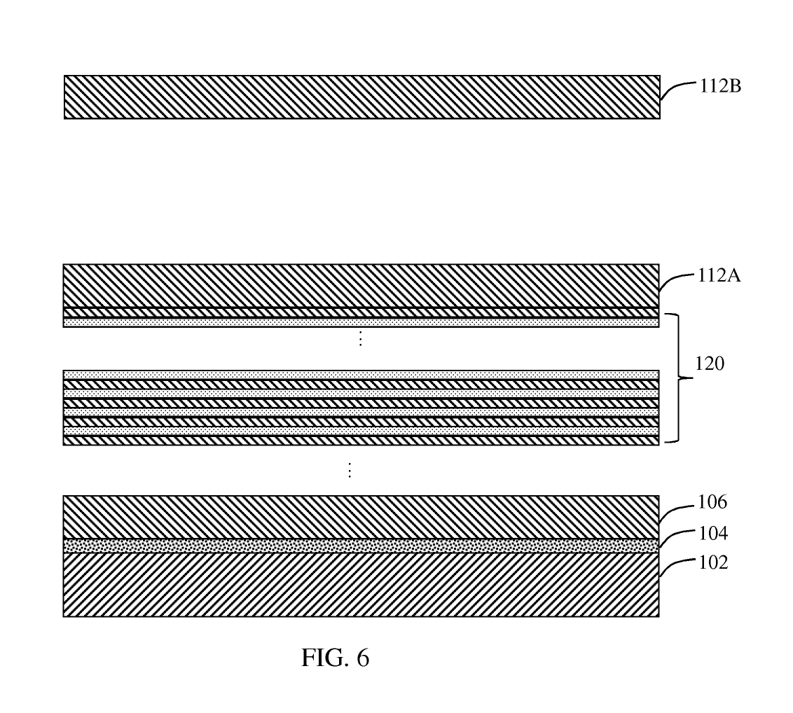

As discussed above, the laser 122 energy is absorbed by InN layer 110 (and all other indices of 110, i.e., 110A, 110B, etc.), causing InN layers 110 to heat up dramatically and locally and thereby decompose into In 107 and N₂ 109. Consequently, the superlattice 120 is broken up and the bond between the thin layer 112 of GaN and the superlattice support structure 120 (or the thick buffer GaN layer 106) is broken. Referring to FIG. 6, Indium 107 and remnants of superlattice 120 (i.e., segments of GaN layers 108) are washed away by a chemical washing process using a washing agent such as isopropanol (“IPA”), hydrochloric acid (“HCl”), or other suitable solvents.

It should be appreciated that the lamellar structure 100 repetition is unlimited within practical limitations, even when using one substrate 102. This repetitive methodology should reduce the total cost of manufacturing high quality GaN, such as thin epilayer of GaN 112. The successive layers can be deposited within a single deposition run in the MOCVD or MBE chamber. By adjusting the power and the pulse duration of the pulsed laser 122, precise control of the laser decomposition process can be achieved. Multiple thin epilayers of GaN 112 may be transferred by using adhesives tapes for transfer onto other substrates.

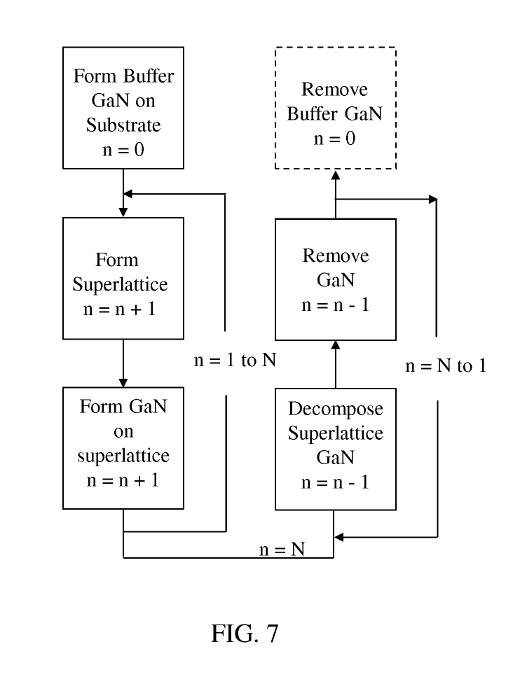

Referring to FIG. 7, a flow chart diagram of various process steps, depicted in FIGS. 3A through FIG. 6, is depicted. It should be noted that the last step in the flowchart of FIG. 7 is an optional step of the removal of the thick buffer GaN layer 106. The removal can be accomplished as depicted in FIG. 2 (i.e., irradiating the GaN-substrate interface with laser). While this method (as discussed above) may result in a high defect GaN layer, it may nevertheless be provided for certain applications.

The current ultra-violet (“UV”) laser lift-off method, widely described in the prior art, is only able to lift off GaN films with a thickness larger than about ten microns (10 μm) due to the high pressure damage at the GaN/Sapphire interface (see FIG. 2). According to several embodiments of the present disclosure, the separation process described herein (i.e., the InN—GaN superlattice separation method) has several advantages over the techniques of the prior art. With the process described here, the amount of Nitrogen gas produced is much smaller, thus thinner layers of GaN can be lift off. For example, GaN thin films within the range of approximately ten nm can be fabricated. It should be appreciated this method can also be used to fabricated thicker layers of GaN (about hundreds of nm thick). It should further be appreciated that no viable methods exist in the prior art to achieve a GaN layer as thin as 10 nm. Even for thicker intermediate thicknesses (e.g., hundreds of nm thick), a significant amount of mechanical planarization is needed according to existing methods described in the prior art. The method disclosed herein lowers materials cost by avoiding wasting a significant amount of GaN as a result of, e.g., mechanical planarization. This method also features an atomically flat finishing surface. Therefore, defect density as low as 10⁵ per cm² can be achieved using the method disclosed herein. The products achieved by the method disclosed herein cover applications from LED luminescence to laser diodes and military radars. In addition, the biocompatibility of GaN may be increased by this liftoff technique for nanometer level devices as well. Thin devices may be implanted into human bodies for various biomedical applications.

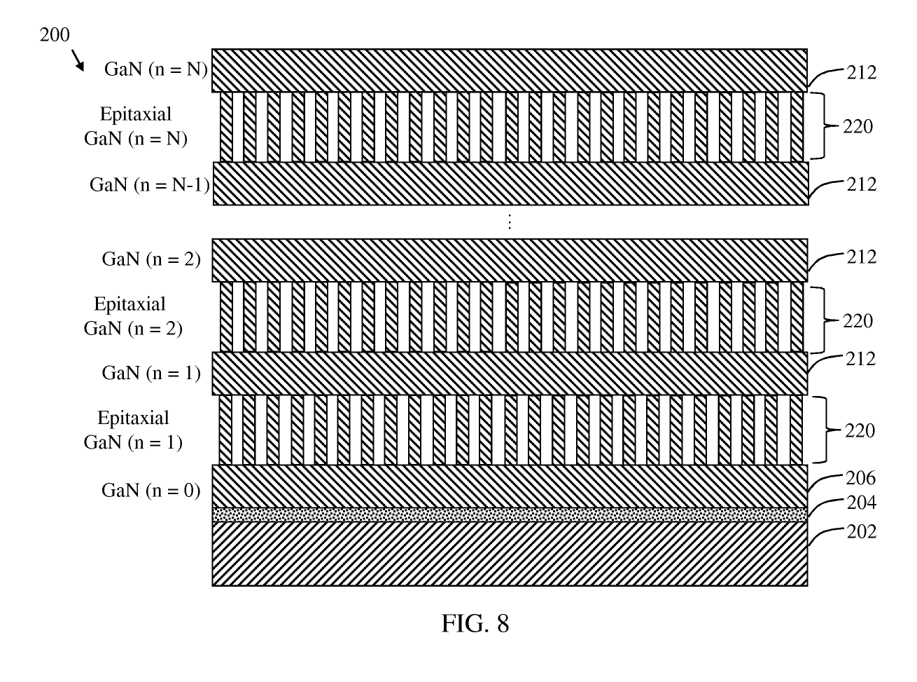

Referring to FIG. 8, a schematic of a lamellar structure 200 is depicted. The lamellar structure 200 includes a substrate 202, a thick buffer GaN layer 206, resulting in a defect rich thin layer 204, and a plurality of a combination of a support structure 220, which includes a plurality of GaN nanorods, described further below, and a thin epilayer 212 of GaN. The substrate 202 can be sapphire as it is known that the combination of sapphire and GaN enables growth of epitaxial crystalline GaN. The thick buffer GaN layer 206 is sufficiently thick to compensate for the lattice mismatch between GaN and the substrate 202. However, the interface region between the substrate 202 and the thick buffer GaN layer 206 results in the defect rich thin layer 204. GaN crystal quality improves as GaN grows thicker.

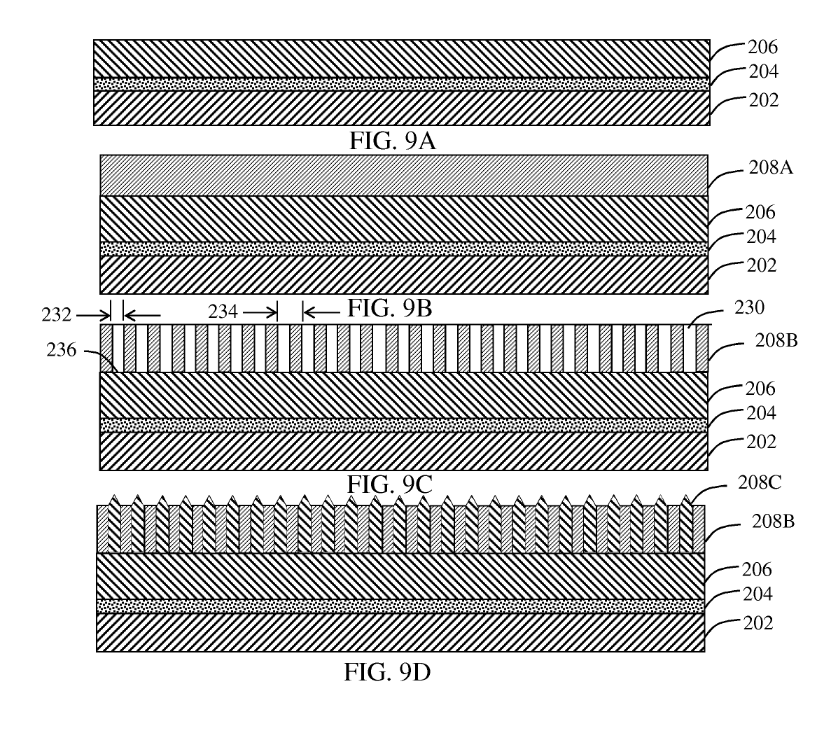

Referring to FIGS. 9A through 9F, various steps to achieve the lamellar structure 200 of FIG. 8 are depicted. Referring to FIG. 9A, the thick buffer GaN layer 206 is formed on the substrate 202. The thick buffer GaN layer 206 is formed according to an epitaxial growth process known to a person having ordinary skill in the art.

Referring to FIG. 9B, a thin metal layer 208A is formed on top of the thick buffer GaN layer 206. The thin metal layer 208A may be aluminum oxide (Al₂O₃) or titanium oxide (TiO₂). The thin metal layer 208A is deposited on top of the GaN surface. Techniques of depositing aluminum may include, but are not limited to ebeam evaporation, plasma sputtering, and atomic layer deposition. In an exemplary embodiment, the thickness of the thin metal layer 208A is about hundred nanometers (100 nm).

Referring to FIG. 9C, the thin metal layer 208A is anodized to a porous anodic alumina 208B. In order to anodize the thin metal layer 208A into the porous anodic alumina 208B, the thin metal layer 208 is to be electropolished in a bath containing chromium oxide, sulfuric acid and phosphoric acid for approximately 20 seconds. Then the backside of the wafer containing these structures and side surfaces are covered and protected by superglue or another polymer. Protection of the backside and side surfaces is to prevent anodization from occurring on the side surfaces of the thin metal layer 208A. The thin metal layer 208A is further anodized in oxalic acid or sulfuric acid within a chiller bath below approximately 5° C. Anodization is completed once the electrical current drops under approximately 0.1 mA.

The porous anodic alumina 208B defines perpendicularly arranged nanopores 230. At the bottom of each nanopore 230 and adjacent to the thick buffer GaN layer 206 (or other thin epilayers 212) and porous anodic alumina 208B interface, thin barrier layer of aluminum oxide 236 separates the porous anodic alumina 208B from the thick buffer GaN layer 206 (or other thin epilayers 212). Etching by either chemical etching in acid or alkali or reactive ion etching (RIE) can be used to open the barrier oxide layers 236, and expose the surface of GaN (206) at the bottom of the nanopores 230. Diameters 232 of the nanopores 230 and inter-pore spacing 234 of the nanopores 230 can be controlled by using different anodization baths and current density.

Referring to FIG. 9D, GaN nanorods 208C are grown. The growth is accomplished by either MOCVD, also known as MOVPE and OMVPE, or MBE. GaN nanorods 208C are perpendicularly grown out of the porous anodic alumina 208B by adjusting growth parameters such as temperature or pressure. For example, high growth temperature, high flux and high pressure each encourage perpendicular growth of GaN nanorods 208C. Growth rate can be monitored by different techniques known to a person having ordinary skill in the art. After GaN nanorods 208C grow out of the porous anodic alumina 208B, growth parameters may be changed.

Referring to FIG. 9E, GaN nanorods 208C (forming the support structure 220) are grown horizontally to form a continuous film, identified as a thin epilayer of GaN 212 (which as discussed below results in higher quality GaN) by adjusting growth parameters known to a person having ordinary skill in the art. For example, low growth temperature and low pressure each encourage horizontal growth of GaN to form a continuous film as identified by the thin layer 212 of GaN. After the formation of the continuous film, GaN may be grown to any desired thickness (i.e., the thickness of the thin epilayer of GaN 212 may be adjusted). This method provides a dislocation filtering effect, known to a person having ordinary skill in the art, which tends to result in higher quality GaN.

Referring to FIG. 9F, the porous anodic alumina 208B has been etched away. Several selective etchants may be used, such as phosphoric acid, sulfuric acid, chromic acid, etc. Heating may improve the etching rate.

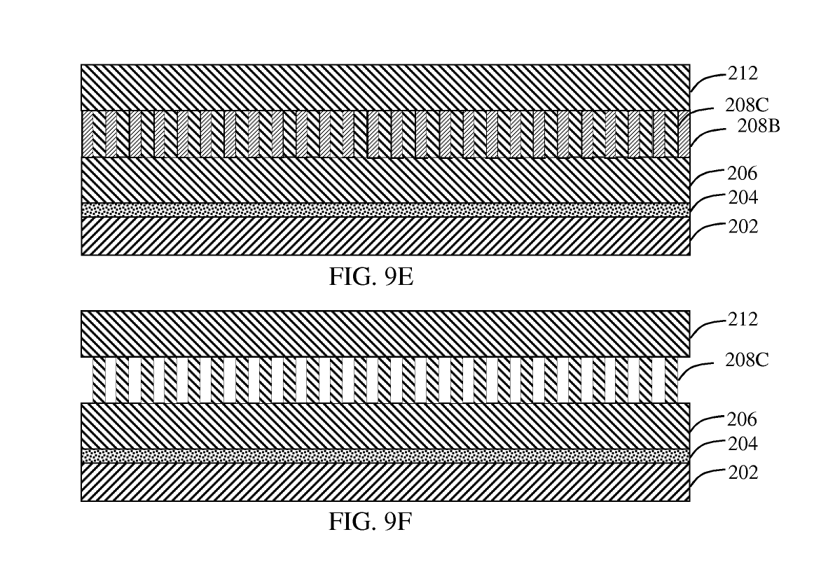

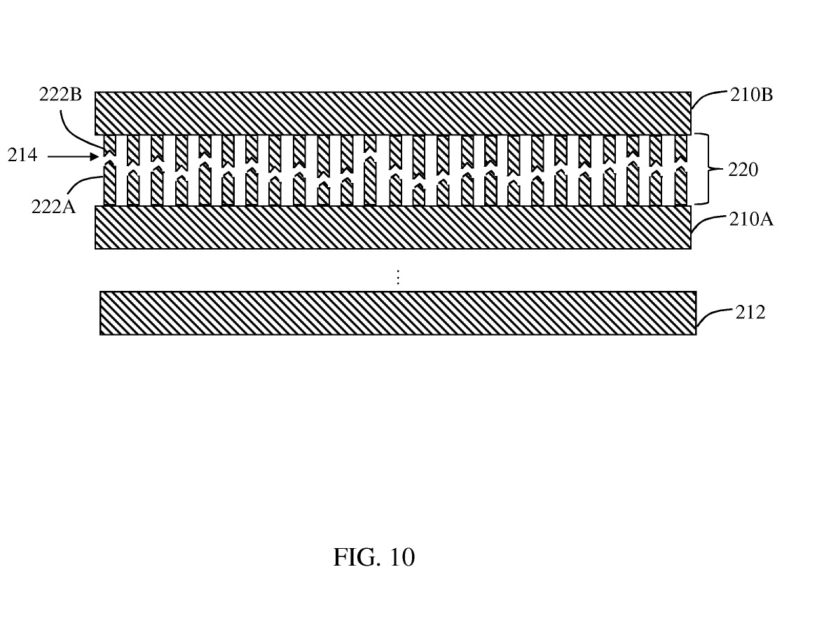

Referring to FIG. 10, after the porous anodic alumina 208B has been etched away, arrow 214 illustrates shearing of the GaN nanorods 208C. Shearing may include disruption by mechanical (including vibrational), thermal (on hot and cold stage), optical (laser), or chemical methods. The GaN nanorods 208C are sheared to form nanorod segments 222A and 222B. The sheared thin layers are identified as 210A and 210B.

Referring to FIG. 11, after shearing the GaN nanorods 208C, higher quality GaN structure 224 and 226 (after the GaN structure 226 has been sheared) having the thin layers 210B and 210A of GaN and GaN nanorod segments 222B and 22A, respectively, may be transferred onto silicon or other suitable substrates. In alternative embodiments, higher quality GaN 224 can be transferred using Scotch tape or similar adhesives without damaging the GaN. In yet another alternative embodiment, GaN nanorod segments 222B and 22A can be processed by mechanical planarization to remove defects due to these segments.

While current commercially available top grade bulk GaN substrates have screw dislocation density from 10⁶ to 10⁷ per cm², methods according to the prior art for producing thin nitride films have had a much higher defect density which makes them unsuitable for device applications. Methods according to embodiments of the present disclosure utilizing the porous aluminum anodic template would be able to generate high level of quality of GaN up to 10⁵ per cm². Furthermore, the thin metal layer 208 can act as a dislocation filtering layer with filtering efficiency as high as about 95%. The method described herein further reduces the dislocation density since threading dislocations are attracted to and annihilated at the surface of nanopores 230 due to the dislocation imaging force. These effects further reduce the dislocation density and produce GaN structures, e.g., GaN structure 224, with dislocation equal to or lower than the best bulk nitride substrates available. The method described herein can also be applied to the substrate 202 multiple times to result in the lamellar structure 200 to further reduce defects and improve crystal quality. As additional layers of GaN are grown, GaN crystal quality improves due to a second order of magnitude reduction in lattice dislocation. After GaN nanorods 208C grow through each porous oxide layer 208B, lattice dislocations are minimized due to the dislocation filtering effect. As a result, sequentially higher and higher quality GaN film can be fabricated. Additionally, it should be appreciated that multiple structures of porous anodic alumina 208B can be selectively etched away. Several selective etchants may be used, such as phosphoric acid, sulfuric acid, chromic acid, etc.

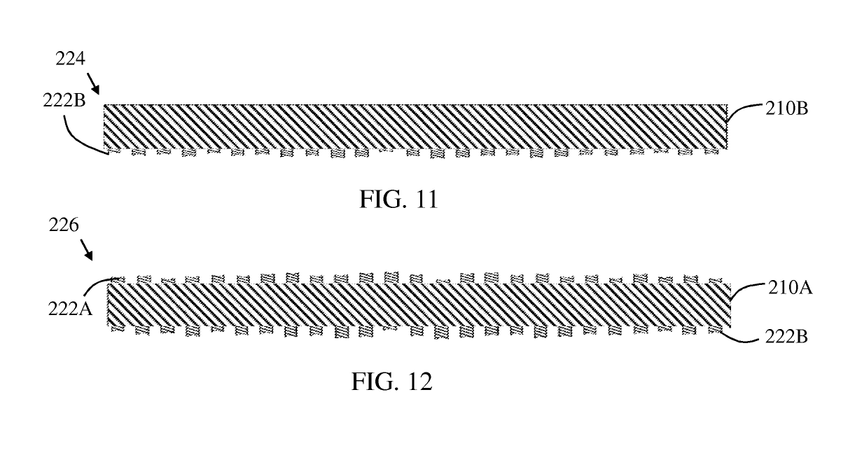

Referring to FIG. 13, a flow chart diagram of various process steps, depicted in FIGS. 9A through FIG. 12, is depicted. It should be noted that the last step in the flowchart of FIG. 13 is an optional step of the removal of the thick buffer GaN layer 206. The removal can be accomplished as depicted in FIG. 2 (i.e., irradiating the GaN-substrate interface with laser). While this method (as discussed above) may result in a high defect GaN layer, it may nevertheless be provided for certain applications.

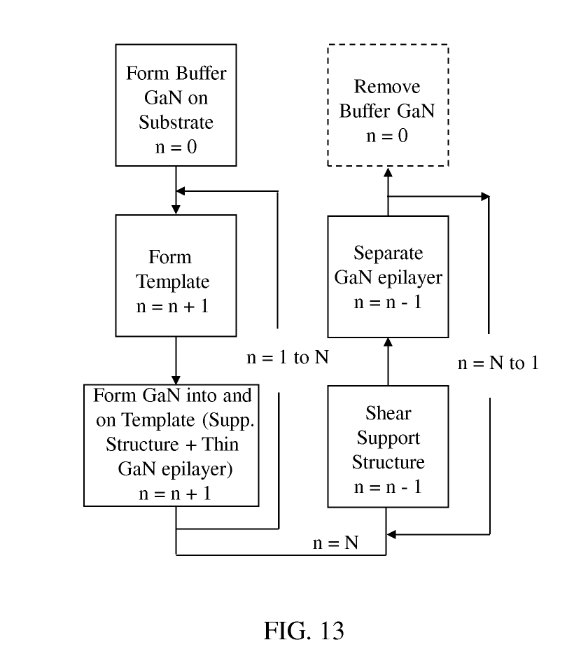

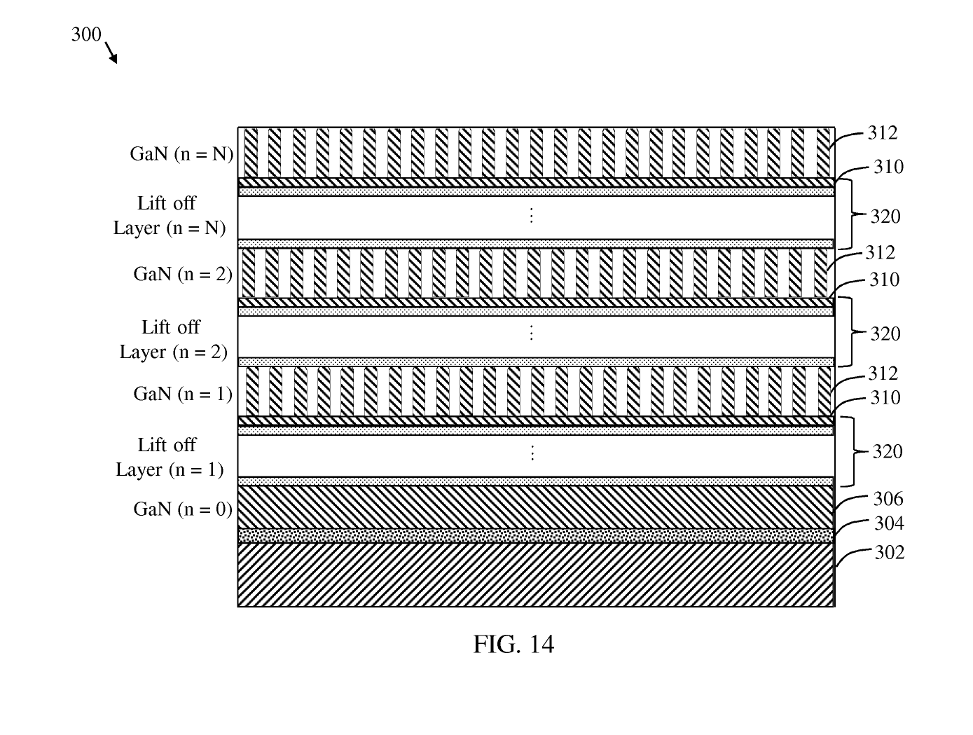

Referring to FIG. 14, a schematic of a lamellar structure 300 is depicted. The lamellar structure 300 includes a substrate 302, a thick buffer GaN layer 306, resulting in a defect rich thin layer 304, and a plurality of a combination of a support structure 320, which includes a plurality of alternating layers of InN and GaN, a thin epilayer of GaN 310, and a porous epitaxial GaN structure 312, described further below. The substrate 302 can be sapphire as it is known that the combination of sapphire and GaN enables growth of epitaxial crystalline GaN. The thick buffer GaN layer 306 is sufficiently thick to compensate for the lattice mismatch between GaN and the substrate 302. However, the interface region between the substrate 302 and the thick buffer GaN layer 306 results in the defect rich thin layer 304. GaN crystal quality improves as GaN grows thicker.

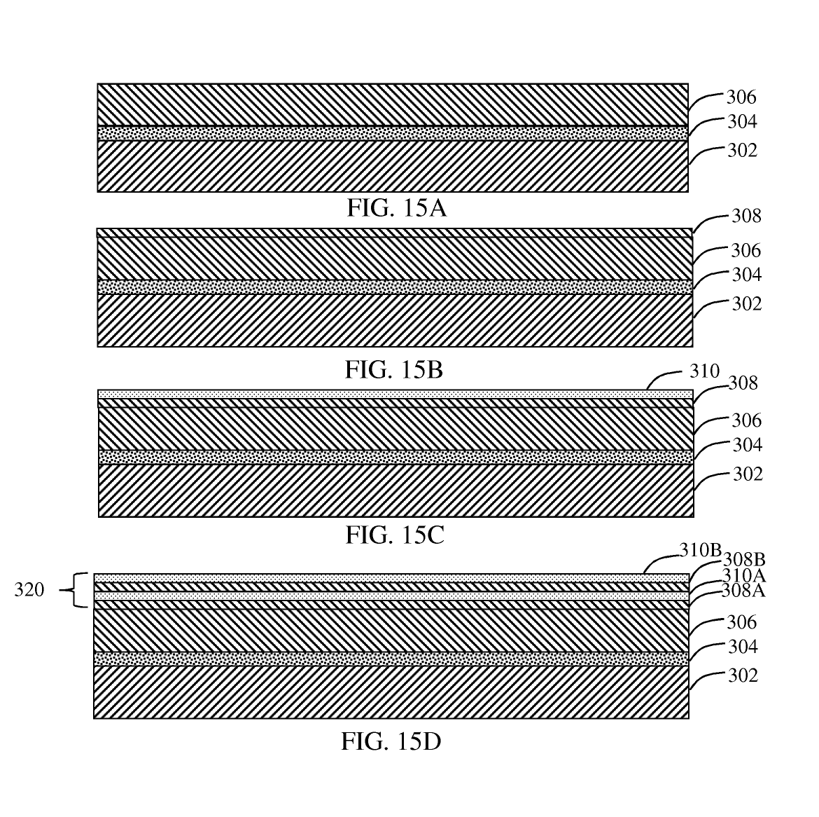

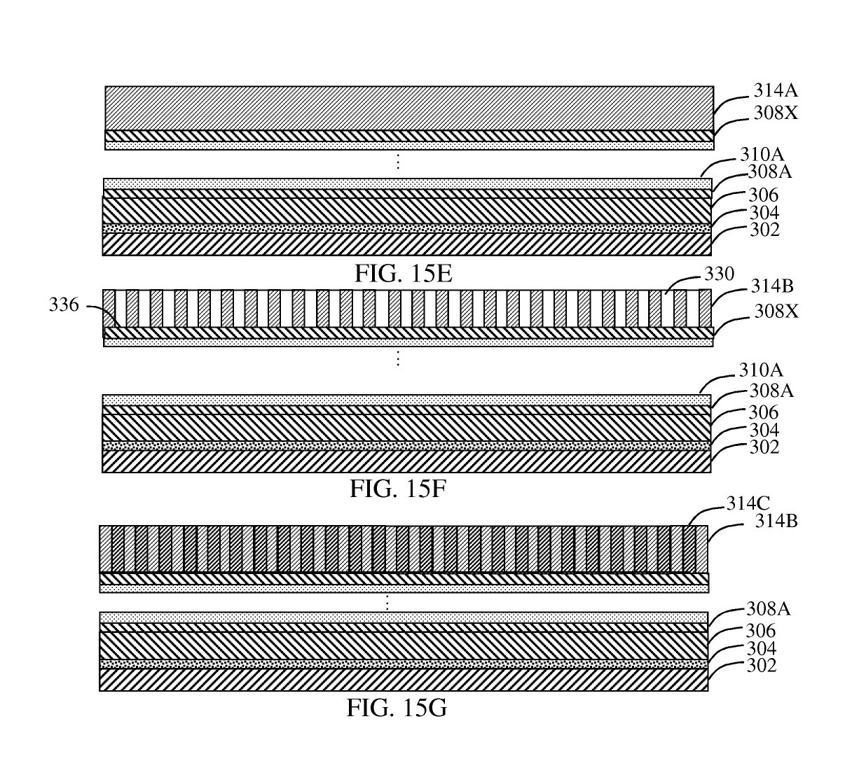

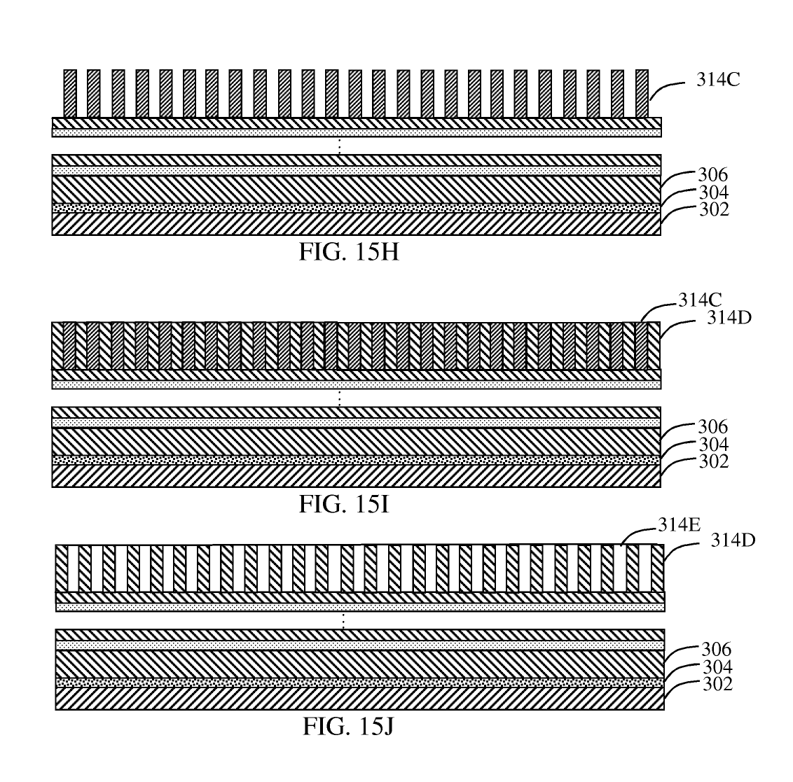

Referring to FIGS. 15A, 15B, 15C, 15D, 15E, 15F, 15G, 15H, 15I, and 15J schematics of various intermediate process steps to achieve the lamellar structure depicted in FIG. 14 are depicted.

Referring to FIG. 15A, the thick buffer GaN layer 306 is formed on the substrate 302. The thick buffer GaN layer 306 is formed according to an epitaxial growth process known to a person having ordinary skill in the art.

Referring to FIG. 15B, an epilayer of GaN 308 is deposited on the thick buffer GaN layer 306. Referring to FIG. 15C, a layer 310 of InN is deposited on top of the epilayer of GaN 308. Thereafter, alternating thin layers 308 and 310 of GaN and InN are deposited to form a support structure 320. These alternating layers are referenced as 308A, 310A, 308B, 310B, and 310X, as depicted in FIGS. 15D and 15E. These layers are alternately deposited by either MOCVD, also known as MOVPE″ and OMVPE, or MBE. Because of the large lattice mismatch between InN and GaN, the critical thickness for InN on GaN is small. Therefore to preserve crystal quality, a very thin layer of InN is needed. To ensure lifting-off over large areas, as well as to compensate for the quantum size effect, multiple alternating layers of InN/GaN are stacked together in the form of a support structure 320. According to an alternative embodiments, within the support structure 320, in place of InN, high Indium composition, high InGaN, can also be used as laser absorption layer, to effect decomposition, as described further below. Low Indium composition, low InGaN, can be used in place of the GaN support structure 320 (with bandgap >2 eV), which could serve to reduce the lattice mismatch and improve epilayer quality. According to another alternative embodiment, high Indium composition layers may take the place of Indium Nitride. Low Indium composition layers may take the place of GaN.

Referring to FIG. 15E, a thin metal layer 314A is formed on top of a GaN layer 308X. The GaN layer 308X can be an atomic monolayer or an epilayer of GaN. The thin metal layer 314A may be aluminum oxide (Al₂O₃) or titanium oxide (TiO₂). The thin metal layer 314A is deposited on top of the GaN surface. Techniques of depositing aluminum may include, but are not limited to ebeam evaporation, plasma sputtering, and atomic layer deposition. In an exemplary embodiment, the thickness of the thin metal layer 314A is about one hundred nanometers (100 nm).

Referring to FIG. 15F, the thin metal layer 314A is anodized to a porous anodic alumina 314B. In order to anodize the thin metal layer 314A into the porous anodic alumina 314B, the thin metal layer 314A is to be electropolished in a bath containing chromium oxide, sulfuric acid and phosphoric acid for approximately 20 seconds. Then the backside of the wafer containing these structures and side surfaces are covered and protected by superglue or another polymer. Protection of the backside and side surfaces is to prevent anodization from occurring on the side surfaces of the thin metal layer 314A. The thin metal layer 314A is anodized in oxalic acid or sulfuric acid within a chiller bath below approximately 5° C. Anodization is completed once the electrical current drops under approximately 0.1 mA.

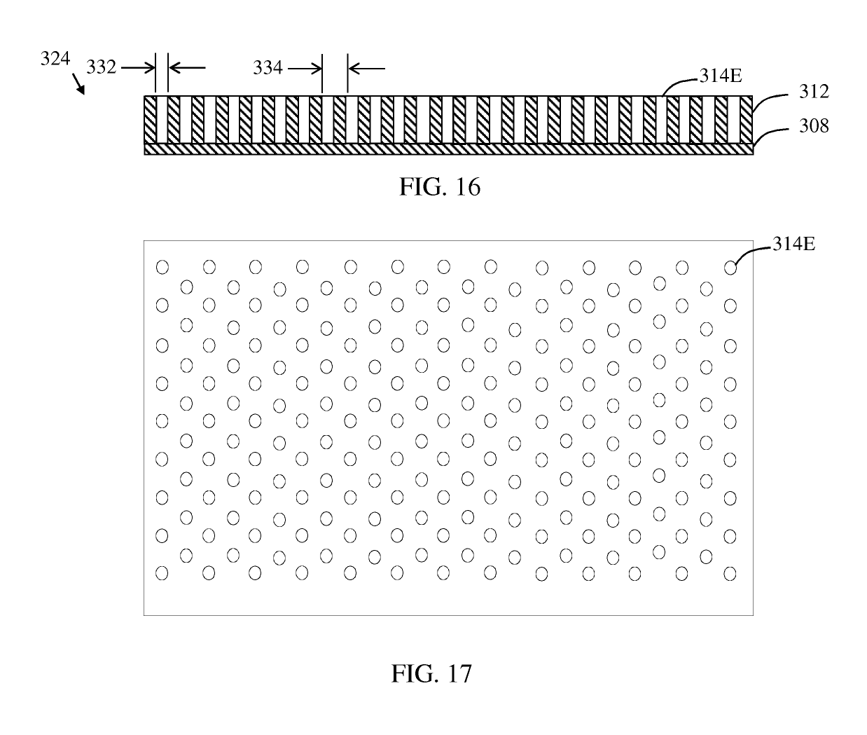

The porous alumina 314B defines perpendicularly arranged nanopores 330. At the bottom of each nanopore 330 and adjacent to the GaN (308, and other indexes of 308, e.g., 308X) and the porous anodic alumina 314B interface, thin barrier layer of aluminum oxide 336 separates the porous alumina 314B from GaN (308). Etching by either chemical etching in acid or alkali or reactive ion etching (RIE) can be used to open the barrier oxide layers 336, and expose the surface of GaN (308) at the bottom of the nanopores 330. Diameters 332 of the nanopores 330 and inter-pore spacing 334 (see FIG. 16) of the nanopores 330 can be controlled by using different anodization chemicals and current density.

Referring to FIG. 15G, after opening bottom oxide barrier layer 336, electrodeposition of metal/semiconductor into the porous anodic alumina 314B to form nanowire array 314C with controllable diameters and spacing. Pourbaix diagrams of electrode posited materials can be referred to control the correct phase and pH of the electrolyte. Mild acidic solution is desired for nanowire growth in porous anodic alumia due to the reaction between acid/alkaline and the oxide.

Referring to FIG. 15H, selective etching of the porous anodic alumina 314B is performed leaving freestanding nanowire array 314C of metal/semiconductor on top of GaN 308X. Selective etchants can be phosphoric acid, sulfuric acid, chromic acid, etc. Heating up the temperature may improve the etching rate.

Referring to FIG. 15I, growth of epitaxial nitride perfumed by either Metal Organic MOCVD, also known as MOVPE and OMVPE, or MBE into the space between nanowires 314C to form nitride/nanowire composite layer 314D (also identified by reference numeral 312). The perpendicular GaN growth will be a substantially true image of the porous anodic alumina 314B. Growth rate can be monitored by different technique. After the GaN growth reaches the desired thickness, and even the thickness exceeds the nanowire length, the Growth direction will be still normal to the substrate. This method provides a dislocation filtering effect which tends to result in higher quality GaN as the thickness increases.

Referring to FIG. 15J, selective etching of metal/semiconductor nanowire array 314C is depicted. This selective etching can be performed electrochemically (applying a positive voltage on nanowire array 314C in electrolyte will etch away nanowires 314C) or chemically (dipping in metal/semiconductor etchants will remove nanowires 314C). The etching results in the formation of nanopores 314E, further depicted in FIGS. 16 and 17. Following removal of nanowire array 314C, a separation process of a flexible GaN structure 324 from the support structure 320 can be accomplished. After that, the flexible GaN structure 324 may be transferred onto silicon or other substrates. In some scenarios, the flexible GaN structure 324 can be transferred using Scotch tape or similar adhesives, and then gets released in a solvent such as acetone.

Referring to FIG. 16, the flexible GaN structure 324 which includes the porous epitaxial GaN structure 312 on top of continuous GaN layer 308 (which may have a thickness as small as ten nanometers) is depicted. Total thickness of flexible GaN structure 324 can be from approximately one hundred nanometers (100 nm) to more than approximately one hundred microns (100 μm). The rigidity and flexural strength is determined by the pore diameter 332 and spacing 334, which can be modeled by finite element method software such as products offered by ANSYS. The porous structure depicted in FIG. 17 is a schematic diagram of the porous epitaxial GaN structure 312.

While current commercially available top grade bulk GaN substrates have screw dislocation density from 10⁶ to 10⁷ per cm², methods disclosed in the prior art for producing thin nitride films have had a much higher defect density which makes them unsuitable for device applications. Methods according to the present disclosure utilize the porous anodic aluminum template which allows retaining the high quality of high quality GaN. Furthermore, thin metal layer 314A can act as a dislocation filtering layer with filtering efficiency as high as about 95%. Methods according to the present disclosure further reduce the dislocation density since threading dislocations are attracted to and annihilated at the surface of nanopores 314E due to the dislocation imaging force. These effects further reduce the dislocation density and produce flexible GaN structure 324 with dislocation equal to or lower than the best bulk nitride substrates available. These methods can also be applied to the substrate multiple times in the lamellar structure 300 to further reduce defects and improve crystal quality.

While the above description applies to generating a porous epitaxial GaN structure by growing GaN according to a template, the porous epitaxial GaN structure can also be formed by an etching process.

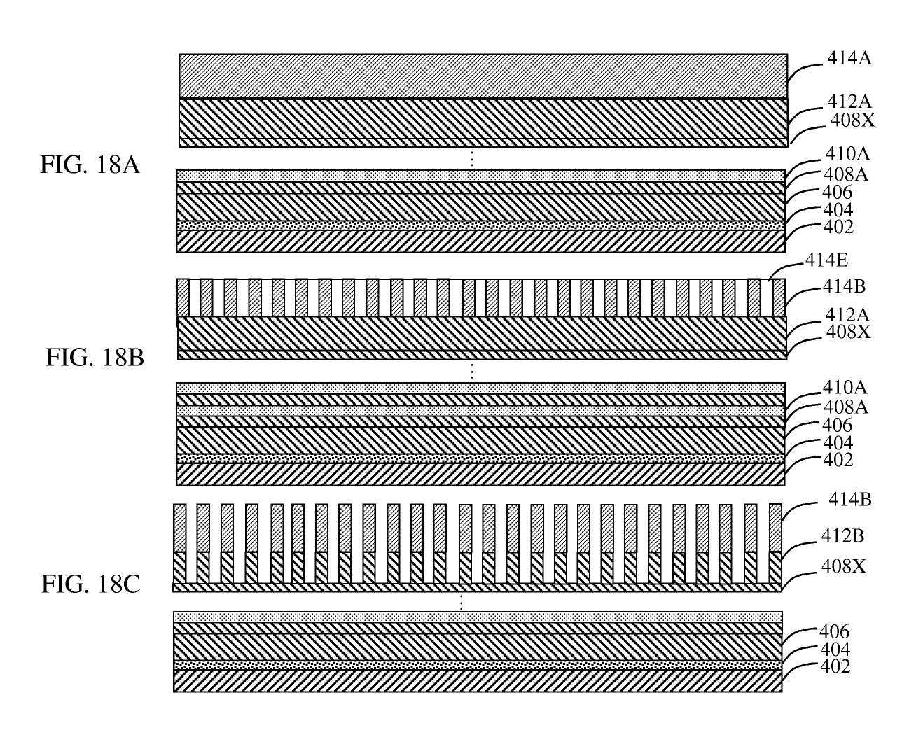

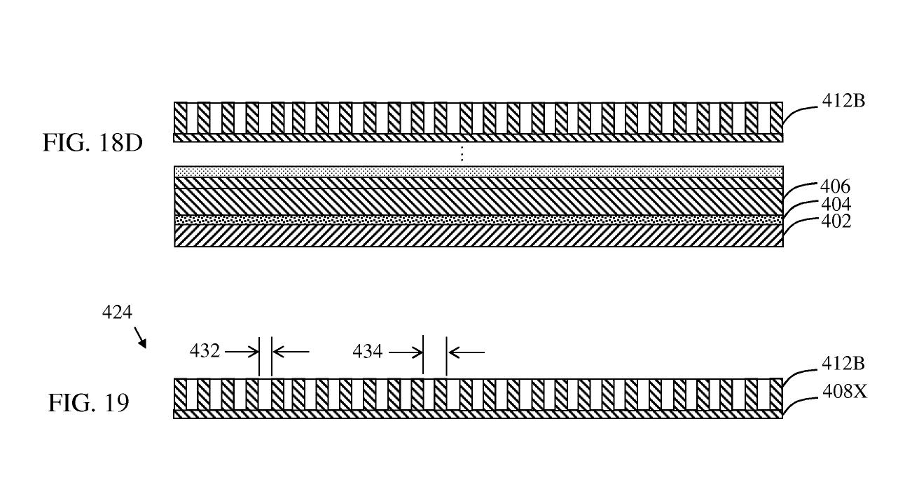

Referring to FIGS. 18A, 18B, 18C, and 18D, schematics of various intermediate process steps to achieve the lamellar structure 300 depicted in FIG. 14 according to an alternative embodiment are presented.

Referring to FIG. 18A, a thin metal layer 414A is formed on top of a GaN epilayer layer 412A which is an epitaxial GaN layer formed on an atomic monolayer of GaN 408X. The atomic monolayer 408X is part of a support structure including alternating layers of InN and GaN (i.e., layers 408A, 410A, and 408X). The support structure is formed on a thick GaN buffer layer 406 which is formed on a substrate 402, resulting in a defect rich layer 404. The thin metal layer 414A may be aluminum oxide (Al₂O₃) or titanium oxide (TiO₂). The thin metal layer 414A is deposited on top of the GaN surface. Techniques of depositing aluminum may include, but are not limited to ebeam evaporation, plasma sputtering, and atomic layer deposition. In an exemplary embodiment, the thickness of the thin metal layer 414A is about one hundred nanometers (100 nm).

Referring to FIG. 18B, the thin metal layer 414A is anodized to a porous anodic alumina 414B. In order to anodize the thin metal layer 414A into a porous anodic alumina 414B, the thin metal layer 414A is to be electropolished in a bath containing chromium oxide, sulfuric acid and phosphoric acid for approximately 20 seconds. Then the backside of the wafer containing these structures and side surfaces are covered and protected by superglue or another polymer. Protection of the backside and side surfaces is to prevent anodization from occurring on the side surfaces of the thin metal layer 414A. The thin metal layer 414A is anodized in oxalic acid or sulfuric acid within a chiller bath below approximately 5° C. Anodization is completed once the current drops under approximately 0.1 mA.

Further referring to FIG. 18B, directional etching is applied from the top of porous anodic alumina 414B. Selective and directional etching methods may include Reactive ion etching (“RIE”), sputter etching, or electro-chemical etching. Prior to etching, a protective layer (such as Au, Ti, or AI) may be deposited on top of porous anodic alumina 414B to protect against premature wear. The etching methods are anisotropic (i.e., the methods are configured to etch the bottom of nanopores 414E and are configured to keep the vertical sidewalls of nanopores 414E intact). The etching methods can be precisely controlled and can be stopped when nanopores 414E come near or reach the GaN layer 408X.

Referring to FIG. 18C, the pattern of nanopores 414E from the porous anodic alumina 414B is transferred by the directional etching method to the underlying GaN layer 412A, resulting in the GaN structure 412B. Pore size 432 (see FIG. 19) and inter-pore spacing (see FIG. 19) are identical or substantially identical to that of the nanopores 414E from porous alumina 414B.

Referring to FIG. 18D, the porous anodic alumina 414B is etched away by etchants such as phosphoric acid, sulfuric acid, chromic acid, etc. The support structure is then broken down by a decomposition process, similar to the laser based decomposition described above. Referring to FIG. 19, a flexible GaN structure 424 which includes the porous epitaxial GaN structure 412B on top of continuous GaN layer 408X (which may have a thickness as small as ten nanometers) is depicted. Total thickness of flexible GaN structure 424 can be from approximately one hundred nanometers (100 nm) to more than approximately one hundred microns (100 μm). The rigidity and flexural strength is determined by the pore diameter 432 and spacing 434, which can be modeled by finite element method software such as products offered by ANSYS.

The methods disclosed herein, provide flexible structures of GaN which have numerous new applications. For example, with flexible GaN substrates it should be possible to fabricate flexible, lightweight, roll-up LED displays. The technique should benefit industries from portable computer/cell phone manufactures to flexible luminescence.

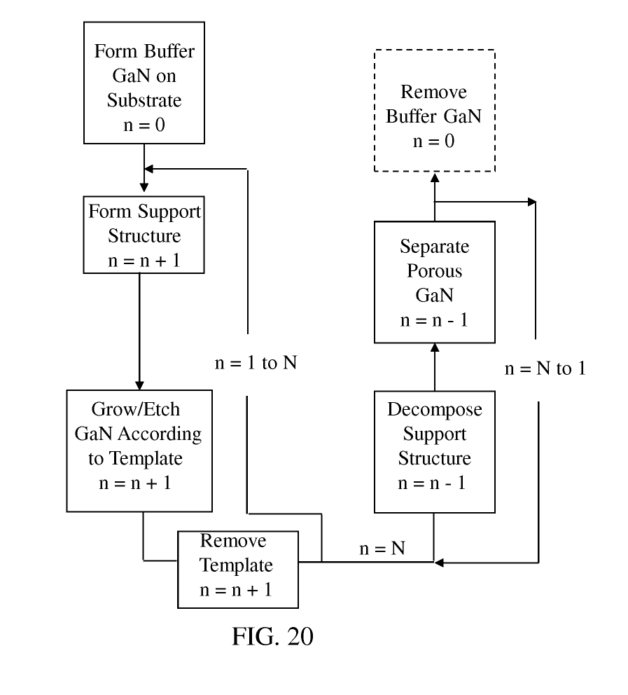

Referring to FIG. 20, a flowchart diagram of various process steps depicted in FIGS. 15A through 15J and FIGS. 18A through 18D is depicted. It should be noted that the last step in the flowchart of FIG. 20 is an optional step of the removal of the thick buffer GaN layer 306 (or 406). The removal can be accomplished as depicted in FIG. 2 (i.e., irradiating the GaN-substrate interface with laser). While this method (as discussed above) may result in a high defect GaN layer, it may nevertheless be provided for certain applications.

Those skilled in the art will recognize that numerous modifications can be made to the specific implementations described above. Therefore, the following claims are not to be limited to the specific embodiments illustrated and described above. The claims, as originally presented and as they may be amended, encompass variations, alternatives, modifications, improvements, equivalents, and substantial equivalents of the embodiments and teachings disclosed herein, including those that are presently unforeseen or unappreciated, and that, for example, may arise from applicants/patentees and others.

1. A material for use in electronic circuits, comprising:
a thin layer of gallium nitride (GaN), the thin layer of GaN produced in a high-volume production setting without mechanical planarization having a thickness of as low as 10 nm and a defect density as low as 10⁵ per cm².

2. The material for use in electronic circuits of claim 1, the thin layer of GaN is configured to be separated from a support structure, the support structure is decomposed prior to the separation, and the support structure includes at least one layer containing indium.

3. The material for use in electronic circuits of claim 2, the separated thin layer of GaN is configured to be flexible.

4. The material for use in electronic circuits of claim 1, the thin layer of GaN is configured to be sheared from a support structure, the support structure is an epitaxial GaN structure, the epitaxial GaN structure has an adjustable and controllable thickness, and the thickness of the epitaxial GaN structure is as low as 50 nm.

5. The material for use in electronic circuits of claim 4, the epitaxial GaN structure includes a plurality of nanorods, the thickness of nanorods and the spacing between the nanorods is adjustable and controllable, the thickness of the nanorods is as low as 5 nm, and the spacing between the nanorods is as low as 5 nm.

6. The material for use in electronic circuits of claim 4, the shearing of epitaxial GaN structure is performed by one of mechanical disruption, optical disruption, thermal disruption, and chemical disruption.

7. The material for use in electronic circuits of claim 4, the sheared thin layer of GaN is configured to be flexible.

8. The material for use in electronic circuits of claim 1, further comprising an epitaxial GaN structure grown on the thin layer of GaN, the epitaxial GaN structure has an adjustable and controllable thickness, and the thickness of the epitaxial GaN structure is as low as 50 nm.

9. The material for use in electronic circuits of claim 8, the epitaxial GaN structure includes a plurality of pores, the diameter of each pore and the spacing between the pores is adjustable and controllable, the thickness of the pores is as low as 5 nm, and the spacing between the pores is as low as 5 nm.

10. The material for use in electronic circuits of claim 9, the combination of the thin layer of GaN and the epitaxial GaN structure is configured to be separated from a support structure, the support structure is disrupted prior to the separation, and the support structure includes at least one layer containing indium.

11. The material for use in electronic circuits of claim 10, the separated combination of the thin layer of GaN and the epitaxial GaN structure is configured to be flexible.

12. A method of making a material for use in electronic circuits produced in a high-volume production setting, comprising:
forming a thick buffer layer of gallium nitride (GaN) on a substrate;
forming a support structure on the thick buffer layer of GaN;
forming a thin epilayer of GaN on top of the support structure;
disrupting the support structure substantially without causing defects in the thin epilayer of GaN; and
removing the thin epilayer of GaN from the disrupted support structure,
the thin epilayer of GaN having a thickness of as low as 10 nm and a defect density as low as 10⁵ per cm².

13. The method of claim 12, the support structure includes at least one layer containing indium.

14. The method of claim 13, the support structure is disrupted by irradiating the support structure with laser, the laser is configured to be absorbed by the support structure and not by GaN.

15. The method of claim 14, the steps of forming the support structure, forming the thin epilayer of GaN, disrupting the support structure, and removing the thin epilayer of GaN are repeated a plurality of times to generate a plurality of removed thin epilayers of GaN.

16. The method of claim 12, forming the support structure includes:
forming a plurality of nanorods according to a template, the thickness of the template being adjustable and controllable and as low as 50 nm, the thickness of the nanorods and the spacing between the nanorods being adjustable and controllable, the thickness of the nanorods being as low as 5 nm, and the spacing between the nanorods being as low as 5 nm.

17. The method of claim 16, the steps of forming the support structure, forming the thin epilayer of GaN, disrupting the support structure, and removing the thin epilayer of GaN are repeated a plurality of times to generate a plurality of removed thin epilayers of GaN.

18. The method of claim 14, further comprising forming an epitaxial GaN structure on the thin epilayer of GaN, the epitaxial GaN structure having a controllable and adjustable thickness, the epitaxial GaN structure includes a plurality of pores, the diameter of the pores and the spacing between the pores being adjustable and controllable, the diameter of the pores is as low as 5 nm, and the spacing between the pores is as low as 5 nm.

19. The method of claim 18, the step of removing the thin epilayer of GaN includes removing the combination of the thin epilayer of GaN and the epitaxial GaN structure.

20. The method of claim 19, forming the epitaxial GaN structure includes growing the epitaxial GaN structure according to a formed template.

21. The method of claim 20, the formation of the template includes:
forming a layer of metal oxide on the thin epilayer of GaN;
anodizing the layer of metal oxide forming a first template structure;
forming a second template structure defined by a nanowire array according to the first template structure;
removing the first template structure;
growing the epitaxial GaN structure according to the second template structure; and
removing the second template structure.

22. The method of claim 21, the metal oxide is one of aluminum oxide and titanium oxide.

23. The method of claim 22, the steps of forming the support structure, forming the thin epilayer of GaN, forming the epitaxial GaN structure, disrupting the support structure, removing the thin epilayer of GaN are repeated a plurality of times to generate a plurality of removed thin epilayers of GaN.

24. The method of claim 19, forming the epitaxial GaN structure includes etching the epitaxial GaN structure according to a formed template.

25. The method of claim 24, the formation of the template includes:
forming a layer of metal oxide on the thin epilayer of GaN;
anodizing the layer of metal oxide forming a first template structure;
etching the thin epilayer of GaN according to the first template structure; and
removing the first template structure.

26. The method of claim 17, the metal oxide is one of aluminum oxide and titanium oxide.

27. The method of claim 26, the steps of forming the support structure, forming the thin epilayer of GaN, forming the epitaxial GaN structure, disrupting the support structure, removing the thin epilayer of GaN are repeated a plurality of times to generate a plurality of removed thin epilayers of GaN.
